(19) United States
(12) Patent Application Publication
(10) Pub. No.: US 2020/0052024 A1
(43) Pub. Date: Feb. 13, 2020

(54) SEMICONDUCTOR SENSORS WITH CHARGE DISSIPATION LAYER AND RELATED METHODS

(71) Applicant: SEMICONDUCTOR COMPONENTS INDUSTRIES, LLC, Phoenix, AZ (US)

(72) Inventors: Richard MAURITZSON, Meridian, ID (US); Bartosz Piotr BANACHOWICZ, San Jose, CA (US); Jon DALEY, Boise, ID (US); Brian Anthony VAARTSTRA, Nampa, ID (US)

(73) Assignee: SEMICONDUCTOR COMPONENTS INDUSTRIES, LLC, Phoenix, AZ (US)

(21) Appl. No.: 16/455,046

(22) Filed: Jun. 27, 2019

Related U.S. Application Data
(60) Provisional application No. 62/717,658, filed on Aug. 10, 2018.

(51) Int. Cl. H01L 27/146; H01L 27/148

(52) U.S. Cl. CPC H01L 27/14625; H01L 27/14806; H01L 27/14621

(57) ABSTRACT

Implementations of image sensors may include a passivation layer coupled over a silicon layer, a color-filter-array coupled over the passivation layer, a lens coupled over the color-filter-array, and at least two optically transmissive charge dissipation layers coupled over the silicon layer.

### CROSS REFERENCE TO RELATED APPLICATIONS

This document claims the benefit of the filing date of U.S. Provisional Patent Application 62/717,658, entitled “Semiconductor Sensors with Charge Dissipation Layer and Related Methods” to Mauritzson, which was filed on Aug. 10, 2018, the disclosure of which is hereby incorporated entirely herein by reference.

### BACKGROUND

### 1. Technical Field

Aspects of this document relate generally to semiconductor sensors. More specific implementations involve image sensors.

### 2. Background

Semiconductor sensors are used in a variety of electronic devices, such as vehicles, smart phones, tablets, and other devices. Image sensors are a type of semiconductor sensor. Image sensors convert light striking a pixel into an electric signal. The electric signal may be processed using a digital signal processor and may be used to make an image.

### SUMMARY

Implementations of image sensors may include a passivation layer coupled over a silicon layer, a color-filter-array coupled over the passivation layer, a lens coupled over the color-filter-array, and at least two optically transmissive charge dissipation layers coupled over the silicon layer.

Implementations of image sensors may include one, all, or any of the following:

One of the at least two optically transmissive charge dissipation layers may be coupled between the lens and the color-filter array.

One of the at least two optically transmissive charge dissipation layers may be coupled between the passivation layer and the color-filter array.

The at least two optically transmissive charge dissipation layers may include a first optically transmissive charge dissipation layer coupled to a first side of the color-filter array and a second optically transmissive charge dissipation layer coupled to a second side of the color-filter-array opposite the first side of the color-filter-array.

Each of the at least two optically transmissive charge dissipation layers may include a thickness less than 0.5 microns.

At least one optically transmissive charge dissipation layer of the at least two optically transmissive charge dissipation layers may include a conductive organic material.

The at least two optically transmissive charge dissipation layers may include one of metallic carbon nanotubes or poly(3, 4-ethylenedioxythiophene):poly(styrenesulfonate).

Implementations of image sensors may include an antireflective layer coupled over a silicon layer, a passivation layer coupled over the antireflective coating layer, a color-filter-array coupled over the passivation layer, a lens coupled over the color-filter-array, and one or more optically transmissive charge dissipation layers coupled between the passivation layer and the lens.

Implementations of image sensors may include one, all, or any of the following:

The one or more optically transmissive charge dissipation layers may be coupled to a ground.

The one or more optically transmissive charge dissipation layers may be electrically floating.

The one or more optically transmissive charge dissipation layers may include a conductive grid aligned with a perimeter of each pixel or a conductive grid aligned with a perimeter of each filter of a plurality of filters of the color-filter array.

The image sensor may be included in a gapless chip-scale package.

The one or more optically transmissive charge dissipation layers may be between the passivation layer and the color-filter-array.

The one or more optically transmissive charge dissipation layers may include a thickness less than 100 angstroms.

Implementations of image sensors may include a passivation layer coupled over a silicon layer, an optically transmissive charge dissipation layer coupled between the passivation layer and the silicon layer, a color-filter-array coupled over the passivation layer, and a lens coupled over the color-filter-array.

Implementations of image sensors may include one, all, or any of the following:

The one or more optically transmissive charge dissipation layers may include a conductive grid.

The one or more optically transmissive charge dissipation layers may include a thickness less than 100 angstroms.

The one or more optically transmissive charge dissipation layers may be grounded.

The one or more optically transmissive charge dissipation layers may be electrically floating.

The image sensor package may include a second passivation layer. The optically transmissive charge dissipation layer may be coupled between the passivation layer and the second passivation layer.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross-sectional side view of a portion of a first implementation of an image sensor;

FIG. 2 is a cross-sectional side view of a cover over the image sensor of FIG. 1;

FIG. 3 is a cross-sectional side view of a portion of a gapless image sensor package;

FIG. 4 is a top view of a conductive grid;

FIG. 5 is a cross-sectional side view of the conductive grid of FIG. 4;

FIG. 6 is a cross-sectional side view of a bond pad portion of a second implementation of an image sensor;

FIG. 7 is a cross-sectional side view of the pixel array portion of the image sensor of FIG. 6;

FIG. 8 is a cross-sectional side view of a bond pad portion of a third implementation of an image sensor;

FIG. 9 is a cross-sectional side view of the pixel array portion of the image sensor of FIG. 8;

FIG. 10 is a cross-sectional side view of a bond pad portion of a fourth implementation of an image sensor; and

FIG. 11 is a cross-sectional side view of the pixel array portion of the image sensor of FIG. 10.

### DESCRIPTION

This disclosure, its aspects and implementations, are not limited to the specific components, assembly procedures or method elements disclosed herein. Many additional components, assembly procedures and/or method elements known in the art consistent with the intended semiconductor sensors will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor sensors, and implementing components and methods, consistent with the intended operation and methods.

The implementations of the charge dissipation layers of the image sensors and image sensor packages disclosed herein may be applied to either backside-illuminated (BSI) imaging products or front side-illuminated (FSI) imaging products. Particular implementations may include complimentary metal-oxide semiconductor (CMOS) image sensor products, charge-coupled device (CCD) image sensor products, or other image sensor (or non-image sensor) products. The sensor packages disclosed herein may be chip-scale packages. While this disclosure primarily refers to image sensors and image sensor packages, it is understood that the various implementations disclosed herein may also be similarly applied to non-image sensor semiconductor packages in order to prevent damage induced through electrostatic discharge (ESD).

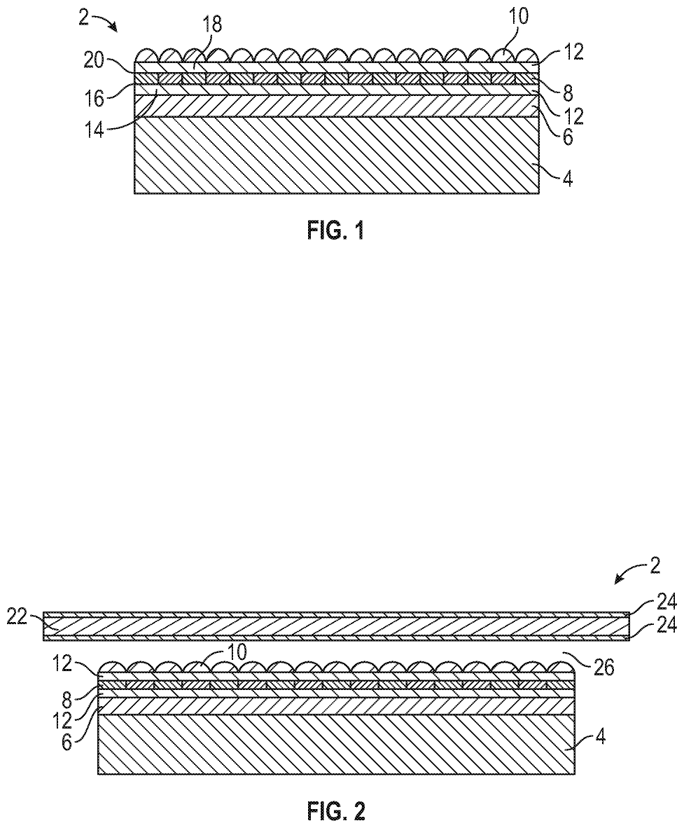

Referring to FIG. 1, a cross-sectional side view of a portion of a first implementation of an image sensor is illustrated. As illustrated, the image sensor 2 may include a silicon layer 4. While a silicon layer is referred to herein, it is understood that the silicon layer in any implementation disclosed herein could be any type of silicon layer including, by non-limiting example, an epitaxial silicon layer, silicon-on-insulator, any combination thereof, or any other silicon-containing layer material. Further, it is also understood that in other implementations an alternative layer other than a silicon-containing layer may be used, such as, by non-limiting example, gallium arsenide, silicon carbide, sapphire, aluminum nitride, or a metal-containing layer in place of the silicon layer. In various implementations, the silicon layer 4 may be between 2.5 to 6 um thick, however, in other implementations the silicon layer, or alternative layer, may be thicker or thinner than this range.

The image sensor 2 may include a passivation layer 6 coupled over the silicon layer 4. The passivation layer may be, by non-limiting example, silicon oxide, silicon nitride, or any other passivation layer material type. In various implementations, and as illustrated, the passivation layer 6 may be directly coupled to the silicon layer 4. In other implementations, one or more layers, including any type of layer disclosed herein, may separate the silicon layer 4 and the passivation layer 6. In other implementations, though not illustrated, an anti-reflecting coating (ARC) layer may be coupled over the passivation layer 6, while in still other implementations the ARC layer may be coupled under the passivation layer 6. The image sensor 2 may include a color-filter-array (CFA) 8 coupled over the passivation layer 6. The image sensor 2 may also include a lens layer 10 coupled over the CFA. The lens layer 10 may include a plurality of micro-lenses.

In various implementations, the image sensor 2 may include one or more charge dissipation layers 12 coupled over the passivation layer 6. The charge dissipation layers 12 may provide conductive pathways that distribute electrostatic discharge. The one or more charge dissipation layers 12 may be optically transmissive, including being transparent or translucent to various wavelengths of light. Because of the optical transmissivity, the charge dissipation layers do not reduce the quantum efficiency (QE), or minimally reduce the QE), of the image sensor. In various implementations, the one or more charge dissipation layers may include, by non-limiting example, a conductive organic material, a carbon nanotube material, Ti, TiO₂, TiO, TiN, indium tin oxide (ITO), TaO, TaOₓ, any other conductive material, and any combination thereof. In implementations of charge dissipation layers including a metal material, the charge dissipation layer may be optically transmissive due to the thickness of the layer or other materials included with the metal material within the charge dissipation layer. In implementations including a charge dissipation layer having a conductive organic material, the conductive organic material may include poly(3,4-ethylenedioxythiophene):poly(styrenesulfonate) (PEDOT:PSS).

In various implementations of charge dissipation layers including conductive organic material, the conductive organic material may be ink jet printed or spun onto a wafer in diluted form and then dried to remove the solvent. In implementations including metallic particles or metallic carbon nanotubes, the conductive materials may be suspended in a polymer forming suspension, such as, by non-limiting example, acrylics, polyimides, polyethylene, terephthalate, or polyesters. In particular implementations, the charge dissipation layers including conductive organic materials or metallic carbon nanotubes may be advantageous in implementations of image sensors and image sensor packages including charge dissipation layers above the CFA due to compatibility with the CFA or lens and due to the low temperature processing which may be necessary with image sensor back-end materials. The one or more charge dissipation layers 12 may be floating or may be electrically grounded. In implementations having a grounded charge dissipation layer, the charge dissipation layer may be coupled to one or more ground pads which may be included in the periphery of the image sensor 2.

In various implementations, and as illustrated by FIG. 1, the image sensor 2 includes two charge dissipation layers. In such implementations, a first charge dissipation layer 14 may be coupled (and may be directly coupled) to a first side 16 of the CFA 8 and the second charge dissipation layer 18 may be coupled (and may be directly coupled) to a second side 20 of the CFA opposite the first side of the CFA. As illustrated by FIG. 1, in various implementations at least one charge dissipation layer is coupled between the passivation layer 6 and the CFA 8. In various implementations, at least one charge dissipation layer is coupled between the lens layer 10 and the CFA 8. While the implementation illustrated by FIG. 1 includes two charge dissipation layers, other implementations may include only a single charge dissipation layer. In various implementations, each of the one or more charge dissipation layers 12 may be less than 0.5 microns thick. In other implementations, the thickness of each charge dissipation layer may be more or less than this, including any thickness disclosed herein.

Referring to FIG. 2, a cross-sectional side view of a cover over the image sensor of FIG. 1 is illustrated. In various implementations, the image sensor 2 may include an optically transmissive cover 22 coupled over the lens layer 10. The image sensor package may include a gap 26 between the cover 22 and the lens layer 10. In particular implementations, the optically transmissive cover 22 may include glass. In various implementations, the optically transmissive cover 22 may be coated on either side, or both sides (as illustrated) with an optically transmissive charge distribution material, which may be any type of charge distribution layer or material disclosed herein. While FIG. 2 illustrates the two charge dissipation layers 12 along with the charge dissipation layers 24, in various implementations the charge dissipation layers 12 may be removed, leaving just the charge dissipation layers 24 coupled to the optically transmissive cover 22. In other implementations, though not illustrated, a charge distribution layer may be coated over the lens layer 10 within the gap 26. The charge distribution layer may be the same as or similar to any charge distribution layer disclosed herein.

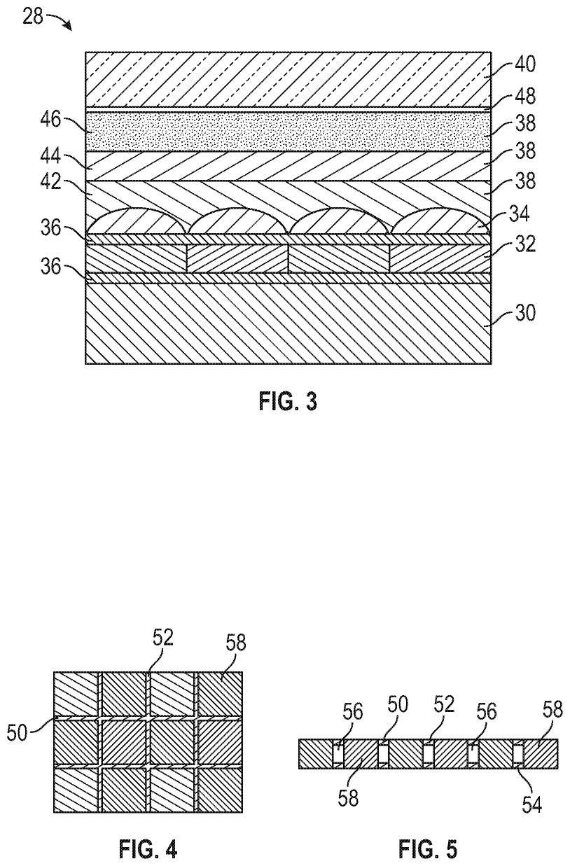

Referring to FIG. 3, a cross-sectional side view of a portion of a gapless image sensor package is illustrated. The image sensor package 28 may include a silicon layer 30 similar to any silicon layer disclosed herein. The image sensor package 28 may include a CFA 32 coupled over the silicon layer 30 and lens layer 34 coupled over the CFA. The lens layer 34 may be the same as or similar to any lens layer disclosed herein. The image sensor package 28 may include one or more charge dissipation layers 36 coupled between the lens layer 34 and the silicon layer 30. In a particular implementation, the image sensor package 28 may include a charge dissipation layer 36 coupled on each side of the CFA. In other implementations, the image sensor package may include only one charge dissipation layer coupled between the silicon layer 30 and the lens layer 34 which may be coupled (and may be directly coupled) over or under the CFA 32. As illustrated, in various implementations a charge dissipation layer may be directly coupled to the silicon layer 30. In various implementations, other layers aside from the charge dissipation layer 36 may separate the CFA 32 from the silicon layer 30. In implementations where the silicon layer 30 is a fully processed silicon layer, the CFA 32 may be directly coupled to the silicon layer. In implementations where the image sensor package 28 is an FSI image sensor package, poly gates, metal routing, backend dielectric layers, and/or other components and/or layers may separate the CFA from the silicon.

As illustrated, the image sensor package 28 may be a gapless image sensor package due to a plurality of layers 38 coupled between the lens layer 34 and the optically transmissive cover 40 (which may be the same as or similar to any other optically transmissive cover disclosed herein). In a particular implementation, the plurality of layers may include, by non-limiting example, an adhesive, a ultra violet (UV) cut layer, a low index layer, an infrared (IR) layer, or an ARC layer. In such implementations, the image sensor package 28 may include a low index layer 42 coupled over the lens layer 34, a UV cut layer 44 coupled over the low index layer, and an adhesive 46 coupled over the UV cut layer. In various implementations, a conductive material, such as metal particles, metallic carbon nanotubes, or any other conductive material disclosed herein, may be incorporated into any of the plurality of layers 38. In such implementations, the adhesive layer, UV cut layer, low index layer, IR layer, or ARC layer may function as a charge dissipation layer. By incorporating the charge dissipation layer into other existing layers, the overall height of the image sensor package may not be increased by the addition of the charge dissipation layers through the incorporation of the conductive material into the existing layers.

Still referring to FIG. 3, in various implementations the image sensor package 28 may include a charge dissipation layer 48 coating the optically transmissive cover 40. The charge dissipation layer 48 may include any type of conductive material disclosed herein. While the image sensor package of FIG. 3 is illustrated as including charge dissipation layers 36 and 48, and also including charge dissipation layers incorporated into the plurality of layers 38, in other implementations the image sensor package may include either the charge dissipation layer 48, one or more of the charge dissipation layers 36, one or more of the charge dissipation layers incorporated into the plurality of layers 38, or any combination thereof.

Referring to FIG. 4, a top view of a conductive grid is illustrated, and referring to FIG. 5, a cross-sectional side view of the conductive grid of FIG. 4 is illustrated. In various implementations, the charge dissipation layer 50 may be patterned into a conductive grid 52. In such implementations, the conductive grid 52 may be aligned with a perimeter of each filter of a plurality of filters of the CFA. In various implementations, multiple grids may be formed as illustrated by the second conductive grid 54 in FIG. 5. The conductive grid or grids may be coupled to a CFA layer which may include a plurality of CFA-in-a-box (CIAB) 58. In various implementations, the conductive grid may be coupled over the wall 56 of the CIAB. In other implementations, the conductive grid may be coupled under the wall 56 of the CIAB. The conductive grid may be coupled over the CIAB or under the CIAB, while in other implementations, as illustrated by FIG. 5, the conductive grid 52 or 54 may be embedded within the CIAB. In such implementations, portions of the CIAB 58 may be etched away prior to embedding the conductive grids in the areas of the removed portions. The conductive grids 52 and 54 may be floating or may be patterned out into the device periphery and coupled to a ground.

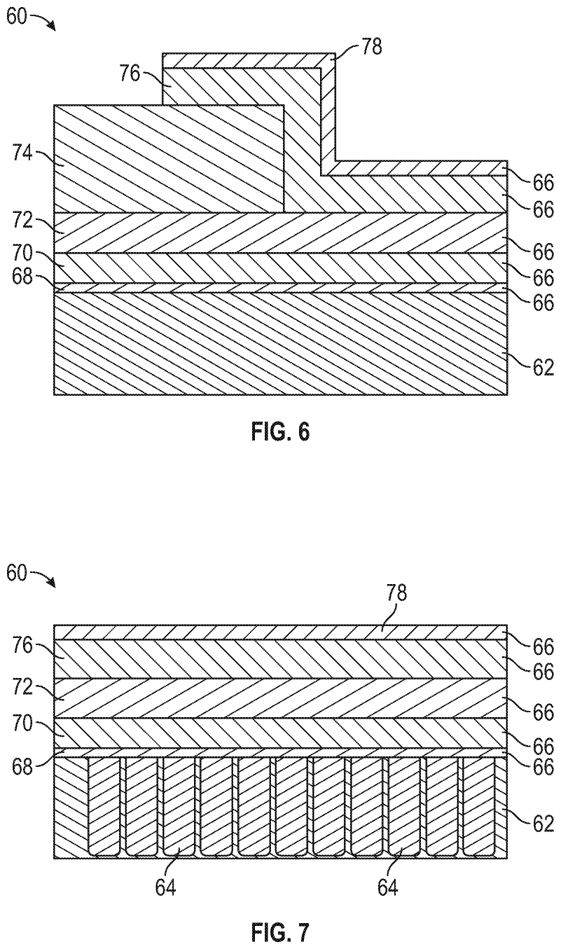

The implementations illustrated by FIGS. 6-11 illustrate the portions of the various image sensors formed under the lens and the CFA. It is understood a CFA, similar to or the same as any CFA disclosed herein, may be coupled over the passivation layer of FIGS. 6-11, and a lens, similar to or the same as any lens disclosed herein, may be coupled over the CFA. It is also understood that any of the charge dissipation layers disclosed herein in relation to FIGS. 1-5 may be included in the image sensors of FIGS. 6-11, though in particular implementations all of the charge dissipation layers included in an image sensor may be illustrated by FIGS. 6-11. Further, it is understood that any of the other layers disclosed in relation to FIGS. 1-5 may be included in the image sensors of FIGS. 6-11. The image sensors of FIGS. 6-11 may be incorporated into image sensor packages which may or may not be gapless.

Referring to FIG. 6, a cross-sectional side view of a bond pad portion of a second implementation of an image sensor is illustrated, and referring to FIG. 7, a cross-sectional side view of the pixel array portion of the image sensor of FIG. 6 is illustrated. In various implementations, the image sensor 60 may include a silicon layer 62. The silicon layer 62 may be the same as or similar to any silicon layer (or alternatives to silicon layers) disclosed herein. As illustrated by FIG. 7, a pixel array 64 may be formed within the silicon layer 62. A plurality of layers 66 may be coupled over the silicon layer 62. As illustrated by FIGS. 6-7, in various implementations a first oxide layer 68 may be coupled over the silicon layer 62. In particular implementations, the first oxide layer 68 may be directly coupled to the silicon layer 62. An ARC layer 70 may be coupled over, and may be directly coupled to, the first oxide layer 68. A second oxide layer 72 may be coupled over, and may be directly coupled to, the ARC layer 70. As illustrated by FIG. 6, a bond pad 74 may be coupled over, and may be directly coupled to, a portion of the second oxide layer 72. The bond pad 74 (and any other bond pad disclosed herein) may include any metal, alloy thereof, other conductive material, or combination thereof. These layers may all have varying thicknesses. In various implementations, the bond pad 74 and/or second oxide layer 72 may each include a thickness between about 1000-8000 Angstroms. In other implementations, the bond pad 74 and/or second oxide layer 72 may include thicknesses greater than or less than 1000-8000 Angstroms. In various implementations, the first oxide layer 68 and/or ARC layer 70 may include a thickness between about 50-1000 Angstroms, however, in other implementations the first oxide layer 68 and/or ARC layer 70 may be more or less thick than 50-1000 Angstroms. Further, as disclosed herein, other implementations of image sensors may not include all of these layers, include more than these layers, include these layers in a different arrangement, or any combination thereof. As illustrated in FIGS. 6-7, the image sensor 60 includes a passivation layer 76 coupled over, and the passivation layer may be directly coupled to, a portion of the bond pad 74 and over a portion of the second oxide layer 72, and to the sidewall of the bond pad 74. The passivation layer may be, by non-limiting example, silicon oxide, silicon nitride, or any other passivation layer material type.

Still referring to the implementation illustrated in FIGS. 6-7, a charge dissipation layer 78 is directly coupled over the passivation layer 76. As illustrated, the charge dissipation layer 78 partially covers the bond pad 74. In other implementations, the charge dissipation layer 78 may more fully cover the bond pad 74, or may not cover the bond pad 74 at all. The charge dissipation layer may be coupled between the passivation layer 76 and a CFA. In various implementations, multiple charge dissipation layers may exist between the passivation layer and the CFA. The charge dissipation layer 78 may include, by non-limiting example, Ti, TiO₂, TiO, TiN, indium tin oxide (ITO), TaO, TaOₓ, any other charge dissipating material disclosed herein, and any combination thereof. The charge dissipation layer 78 is electrically conductive and may be optically transmissive, including being transparent or translucent to various wavelengths of light. The charge dissipation layer 78 may have varying thicknesses. In various implementations, the charge dissipation layer 78 may have a thickness from about 50 A to 500 A, however, other implementations may include a charge dissipation layer having a thickness less than 50 A or greater than 500 A. Particular implementations of charge dissipation layers include, among others, a TiO or TiO₂ layer 50 A thick, a TiO or TiO2 layer 100 A thick, a TiO or TiO2 layer 300 A thick, and a Ti layer 50 A thick.

In various implementations, a method of forming a charge dissipation layer may include depositing a metal or other conductive layer over the second oxide layer 72 and etching or patterning the metal or other conductive layer to form the bond pad 74. The method may include forming the passivation layer 76 over the bond pad 74 and the top oxide layer 72, and then forming the charge dissipation layer 78 over the passivation layer 76. The charge dissipation layer 78 may be deposited through sputtering, chemical vapor deposition, combinations of physical and chemical vapor deposition, spin coating, ink-jet printing, screen printing, or any other process of forming a layer on the material over the passivation layer material. In various implementations, the charge dissipation layer 78 is patterned and both the charge dissipation layer and the passivation layer 76 are etched in a single etch. In other implementations, the charge dissipation layer 78 is etched through a first etch and the passivation layer 76 is etched through a second etch.

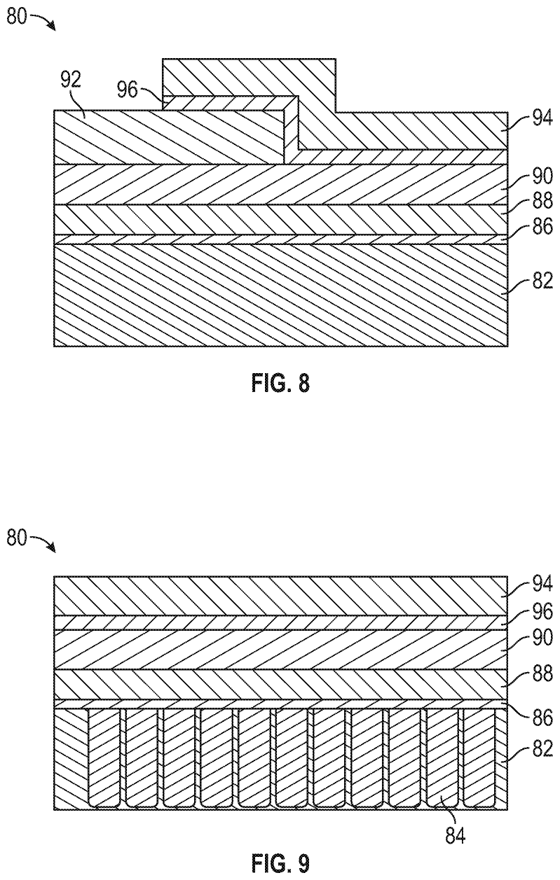

Referring to FIG. 8, a cross-sectional side view of a bond pad portion of a third implementation of an image sensor is illustrated, and referring to FIG. 9, a cross-sectional side view of the pixel array portion of the image sensor of FIG. 8 is illustrated. The image sensor of FIGS. 8-9 may be similar to the image sensor of FIGS. 6-7 inasmuch as the image sensor may include a silicon layer 82 having a pixel array 84. The image sensor 80 may include a first oxide layer 86 coupled over the silicon layer 82, an ARC layer 88 coupled over the first oxide layer 86, a second oxide layer 90 coupled over the ARC layer 88, and a bond pad 92 coupled over the second oxide layer 90. These layers may be the same as the respective layers of FIGS. 6-7. The image sensor 80 may also include a passivation layer 94 and a charge dissipation layer 96 similar to the passivation layer 76 and the charge dissipation layer 78 of FIGS. 6-7, with the difference being that the passivation layer 94 may be coupled over the charge dissipation layer 96. In such an implementation, the charge dissipation layer may be directly coupled to and over the second oxide layer 90 and a portion of the bond pad 92. Accordingly, the charge dissipation layer 96 is coupled between the passivation layer 94 and the silicon layer 82. The charge dissipation layer may include any type of charge dissipation layer material previously disclosed herein. In particular implementations, the charge dissipation layer may include, among others, a TiO or TiO2 layer about 50 A thick, a TiO or TiO2 layer about 100 A thick, a TiO or TiO2 layer about 300 A thick, and a Ti layer about 50 A thick. Other implementations may include similar layers having thickness more or less than those listed herein.

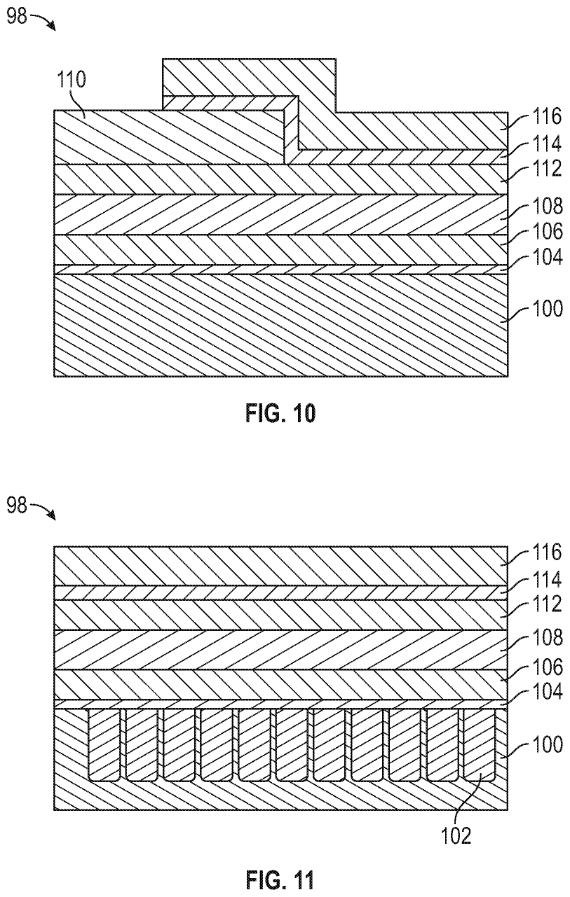

Referring to FIG. 10, a cross-sectional side view of a bond pad portion of a fourth implementation of an image sensor is illustrated, and referring to FIG. 11, a cross-sectional side view of the pixel array portion of the image sensor of FIG. 10 is illustrated. The image sensor of FIGS. 10-11 may be similar to the image sensor of FIGS. 8-9 in as much as the 98 may include a silicon layer 100 having a pixel array 102. The 98 may include a first oxide layer 104 coupled over the silicon layer 100, an ARC layer 106 coupled over the first oxide layer 104, and a second oxide layer 108 coupled over the ARC layer 106. These layers may be the same as the respective layers of FIGS. 8-9. Different from the implementations illustrated by FIGS. 6-9, the image sensor 98 may include a second passivation layer 112 coupled over the second oxide layer 108. The second passivation layer 112 may include any type and any thickness of any other passivation layer disclosed herein. The image sensor 98 may also include a bond pad 110 coupled over the second passivation layer 112. In various implementations, the image sensor 98 may include a charge dissipation layer 114 which may be directly coupled to and over the second passivation layer 112 and a portion of the bond pad 110. The charge dissipation layer may include any type of charge dissipation layer material previously disclosed herein. In particular implementations, the charge dissipation layer may include, among others, a TiO or TiO2 layer about 50 A thick, a TiO or TiO2 layer about 100 A thick, a TiO or TiO2 layer about 300 A thick, and a Ti layer about 50 A thick. Other implementations may include similar layers having thickness more or less than those listed herein. As illustrated by FIGS. 10-11, the image sensor includes a first passivation layer 116 coupled over the charge dissipation layer 114. Accordingly, the charge dissipation layer 114 may be coupled between the first passivation layer 116 and the second passivation layer 112. The first passivation layer 116 may be the same as or similar to any passivation layer disclosed herein. While the implementation illustrated by FIGS. 10-11 is described herein as including a first and a second passivation layer, the image sensor of FIGS. 10-11 may alternatively be considered as having the charge dissipation layer embedded within a single passivation layer.

As illustrated by FIGS. 8 and 10, the bond pad 92 and 110 may be a ground bond pad as it is directly coupled to the respective charge dissipation layers 96 and 114. In such implementations, the charge dissipation layer is grounded. In other implementations having a floating charge dissipation layer, the charge dissipation layer may not overlap the bond pad.

In various implementations, a method for forming a dissipation layer below a passivation layer may include forming a metal or other conductive layer over the second oxide layer 90 of FIG. 8 or over the second passivation layer 112 of FIG. 10. The method may include etching or patterning the metal or other conductive layer and forming a bond pad. The method may include forming the charge dissipation layer over the bond pad 92 and over the oxide layer 90 (FIG. 8), or over the bond pad 110 and over the second passivation layer 112 (FIG. 10). The charge dissipation layer may be deposited through sputtering, chemical vapor deposition, a combination of physical vapor deposition and chemical vapor deposition, spin coating, ink-jet printing, screen printing, or any other process of forming a layer on the material over the passivation layer material. The method may include forming a passivation layer over the charge dissipation layer. In various implementations, the charge dissipation layer is patterned and etched prior to deposition of the passivation layer formed over the charge dissipation layer. In other implementations, the passivation layer is patterned and both the charge dissipation layer and the passivation layer formed over the charge dissipation layer are etched in a single etch. In other implementations, the passivation layer formed over the charge dissipation layer is etched through a first etch and the charge dissipation layer is etched through a second etch.

In various implementations, the charge dissipation layer may be formed below a color filter array (CFA) and/or the lens. In other implementations, the charge dissipation layer may be formed over the color filter array and/or lens, and in still other implementations, the charge dissipation layer could be formed and/or integrated within the structure of a color filter array and/or the lens. While the implementations illustrated by FIGS. 6-11 illustrate the passivation layer directly coupled to the charge dissipation layer, in other implementations the passivation layer may not be directly coupled to the charge dissipation layer. Similarly, while the implementations illustrated by FIGS. 6-11 illustrate the charge dissipation layer formed above the bond pad and/or top oxide layer (FIG. 8), or first passivation layer (FIG. 10), in other implementations the charge dissipation layer may be located beneath other layers and/or closer to the silicon layer.

In various implementations of image sensors and image sensor packages disclosed herein, the charge dissipation layers may be floating, in as much as it is not electrically connected to or coupled with any other electrically grounded or biased layer or structure in the image sensor or image sensor package. In such implementations, the charge dissipation layers protect against ESD events/effects by evenly distributing the charge across the wafer or die rather than allowing the charge to be trapped in underlying dielectric layers or otherwise locally concentrated in areas of the device. In other implementations, the charge dissipation layers may be electrically tied with a ground. In such implementations, the charge dissipation layers may be directly coupled to a ground pad. In such implementations, the charge dissipation layers may be patterned and/or etched to ensure that it is only electrically coupled to the ground pad. In such implementations, the charge dissipation layers protect against ESD events/effects by draining the charge to the ground rather than allowing the charge to remain trapped in underlying dielectric layers.

In various implementations of the image sensors and image sensor packages disclosed herein, the charge dissipation layer may be a solid and continuous layer. In other implementations, any of the charge dissipation layer may be patterned into a grid. In such implementations, the center area of each pixel in the pixel array may be exposed through the grid as a mechanism for minimizing QE loss caused by the material of the charge dissipation layer. In implementations having a grid, the charge dissipation layer may or may not be optically transmissive as the material of the charge dissipation layer need not be transparent to the same wavelengths used to calculate the optimal sensor QE (which depends on the particular wavelength(s) of light the sensor is designed to detect). In implementations having a grid, the grid width may be as small as about 0.25 to about 1.0 um wide (for 1 um to about a 4 um pixel). In other implementations, the widths may be narrower than about 0.25 um or wider than about 1.0 um.

Various implementations of the image sensors and image sensor packages disclosed herein may include charge dissipation layer or layers capable of enabling charge dissipation and even distribution of charges resulting from ESD events, both air and direct contact discharge, up to at least 30 kV in implementations where the charge dissipation layer is floating.

The various implementations of image sensors and image sensor packages having charge dissipation layers disclosed herein may unexpectedly improve the dark signal ratio between the active array pixels and the optically black reference pixels. In such implementations, the ratio may be improved due to the charge dissipation layers ameliorating any charging of the pixel material accumulated during etching steps used to form the pixels in the fabrication process.

The various implementations of charge dissipation layers disclosed herein may have a minimal negative effect, and in some implementations no effect at all, on QE, indicating that the charge dissipation layer does not unduly affect light transmission (was sufficiently transparent or translucent). Further, the image sensors and image sensor packages disclosed herein may have a dark shading profile, or dark signal, that is more uniform across the entire image sensor array. The charge dissipation layers disclosed herein may also reduce the number of hot or white pixels and greatly decrease the dark signal non-uniformity (DSNU) of the various image sensors.

In places where the description above refers to particular implementations of image sensors and image sensor packages and implementing components, sub-components, methods and sub-methods, it should be readily apparent that a number of modifications may be made without departing from the spirit thereof and that these implementations, implementing components, sub-components, methods and sub-methods may be applied to other image sensors and image sensor packages.

What is claimed is:

1. An image sensor comprising:
a passivation layer coupled over a silicon layer;
a color-filter-array coupled over the passivation layer;
a lens coupled over the color-filter-array; and
at least two optically transmissive charge dissipation layers coupled over the silicon layer.

2. The image sensor of claim 1, wherein one of the at least two optically transmissive charge dissipation layers is coupled between the lens and the color-filter array.

3. The image sensor of claim 1, wherein one of the at least two optically transmissive charge dissipation layers is coupled between the passivation layer and the color-filter array.

4. The image sensor of claim 1, wherein the at least two optically transmissive charge dissipation layers comprise a first optically transmissive charge dissipation layer coupled to a first side of the color-filter array and a second optically transmissive charge dissipation layer coupled to a second side of the color-filter-array opposite the first side of the color-filter-array.

5. The image sensor of claim 1, wherein each of the at least two optically transmissive charge dissipation layers comprise a thickness less than 0.5 microns.

6. The image sensor of claim 1, wherein at least one optically transmissive charge dissipation layer of the at least two optically transmissive charge dissipation layers comprise a conductive organic material.

7. The image sensor of claim 1, wherein the at least two optically transmissive charge dissipation layers comprise one of metallic carbon nanotubes or poly(3,4-ethylenedioxythiophene):poly(styrenesulfonate).

8. An image sensor comprising:
an antireflective coating layer coupled over a silicon layer;
a passivation layer coupled over the antireflective coating layer;
a color-filter-array coupled over the passivation layer;
a lens coupled over the color-filter-array; and
one or more optically transmissive charge dissipation layers coupled between the passivation layer and the lens.

9. The image sensor of claim 8, wherein the one or more optically transmissive charge dissipation layers are coupled to a ground.

10. The image sensor of claim 8, wherein the one or more optically transmissive charge dissipation layers are electrically floating.

11. The image sensor of claim 8, wherein the one or more optically transmissive charge dissipation layers comprise a conductive grid aligned with a perimeter of each pixel or a conductive grid aligned with a perimeter of each filter of a plurality of filters of the color-filter array.

12. The image sensor of claim 8, wherein the image sensor is comprised in a gapless chip-scale package.

13. The image sensor of claim 8, wherein the one or more optically transmissive charge dissipation layers is between the passivation layer and the color-filter-array.

14. The image sensor of claim 8, wherein the one or more optically transmissive charge dissipation layers comprise a thickness less than 100 angstroms.

15. An image sensor comprising:
a passivation layer coupled over a silicon layer;
an optically transmissive charge dissipation layer coupled between the passivation layer and the silicon layer;
a color-filter-array coupled over the passivation layer; and
a lens coupled over the color-filter-array.

16. The image sensor of claim 15, wherein the one or more optically transmissive charge dissipation layers comprise a conductive grid.

17. The image sensor of claim 15, wherein the one or more optically transmissive charge dissipation layers comprise a thickness less than 100 angstroms.

18. The image sensor of claim 15, wherein the one or more optically transmissive charge dissipation layers are grounded.

19. The image sensor of claim 15, wherein the one or more optically transmissive charge dissipation layers are electrically floating.

20. The image sensor of claim 15, further comprising a second passivation layer, wherein the optically transmissive charge dissipation layer is coupled between the passivation layer and the second passivation layer.
